(19) United States
(12) Patent Application Publication
(10) Pub. No.: US 2018/0213633 A1
(43) Pub. Date: Jul. 26, 2018

(54) Heat Dissipator with Circuit Formed by Screen Printing or Spraying

(71) Applicant: Shiu Li Technology Co., Ltd., Kunshan City (CN)

(72) Inventor: Chung-Cheng Chien, Taoyuan City (TW)

(73) Assignee: Shiu Li Technology Co., Ltd.

(21) Appl. No.: 15/499,586

(22) Filed: Apr. 27, 2017

(30) Foreign Application Priority Data
Jan. 20, 2017 (TW) 106201056

(51) Int. Cl. H05K 1/02; H05K 3/46; H05K 3/12

(52) U.S. Cl. CPC H05K 1/0201; H05K 3/4664; H05K 2203/0736; H05K 2201/066; H05K 3/1216

(57) ABSTRACT

A heat dissipator having a circuit formed by screen printing or spraying includes a circuit layer and an isolation layer. The circuit layer, which is on a surface of a heat dissipation part of the heat dissipator having the circuit formed by screen printing or spraying, is formed by screen printing or spraying a uniformly distributed plastic material and low electrical resistance conductive powder. The isolation layer is disposed on the circuit layer and the heat dissipation part.

### CROSS-REFERENCE TO RELATED APPLICATION

This application claims priority from Taiwan Patent Application No. 106201056, filed on Jan. 20, 2017 at the Taiwan Intellectual Property Office, the content of which is hereby incorporated by reference in its entirety for all purposes.

### BACKGROUND OF THE INVENTION

### 1. Field of the Invention

The present invention relates to a heat dissipator. More particularly, the present invention relates to a heat dissipator having a circuit that is formed by a method of screen printing or spraying.

### 2. Description of the Related Art

There are several applications of an illumination device, such as street lighting, interior illumination, lights for advertising display, lights used in equipment, etc. Normally, light sources such as incandescent lamps, fluorescent tube lighting, or mercury lamps are used in these illumination devices. However, these light sources have disadvantages of low efficiency and high electricity consumption, and the mercury vapor within these sources is a toxic pollutant to our environment. Moreover, these light sources suffer the problems of being easily damaged or have short lifetimes and have to be fixed or exchanged frequently wasting time, material, and manpower. Therefore, there is a need to improve the situation.

Currently, the solid state light emitting diode (LED) lighting is considered a replacement for the aforementioned light sources in the aforementioned illumination devices, as it is an improvement in illumination efficiency and consumes less electricity. Implementation of this kind of light source requires a number of LEDs to be placed on a circuit substrate. The greater the number of LEDs and output power, then the greater the amount of heat that is generated during the energy conversion process between electricity and light. As a result, temperatures of devices with more LEDs and higher output power can become higher. This extra heat needs to be dissipated through an isolation layer of the circuit substrate to a heat dissipator and fins.

The circuit substrate for the LEDs is glued onto the surface of the heat dissipator, and this means that it is likely that the two surfaces do not form a close enough, secure and tight-fitting seal. This affects the heat dissipation efficiency and rate, through a degradation of the thermal conduction efficiency arising from, for example, aging and peeling problems that may easily occur. As a consequence, after a period of use, the temperature of LEDs becomes high and the light output of the LEDs decreases, which affects the lumen depreciation of the LEDs over time and so shortens their lifetime.

### SUMMARY OF THE INVENTION

In view of the aforementioned issue, the purpose of the present invention is to provide a heat dissipator having a circuit formed by screen printing or spraying to resolve the problem of the conventional approach.

Therefore, for this purpose, the present invention provides a heat dissipator having a circuit formed by screen printing or spraying, including a circuit layer and an isolation layer. The circuit layer is on a surface of a heat dissipation part of the heat dissipator having the circuit formed by screen printing or spraying and is formed by screen printing or spraying a uniformly distributed plastic material and a low electrical resistance conductive powder. The isolation layer is disposed on the circuit layer and the heat dissipation part.

Preferably, the heat dissipation part may be a metal heat dissipation part, and a heat conductive isolation layer is disposed between the heat dissipation part and the circuit layer by screen printing or spraying a material that includes a uniformly distributed heat conductive powder.

Preferably, the heat conductive powder may include crystalline particles with spherical or irregular shape.

Preferably, the particle size of the heat conductive powder may be in a range from 0.01 μm to 100 μm.

Preferably, the thickness of the heat conductive isolation layer may be in a range from 0.01 mm to 15 mm.

Preferably, there may be a plurality of fins on the other surface of the heat dissipation part.

Preferably, the heat dissipation part may be a ceramic heat dissipation part, a plastic heat dissipation part, or a glass heat dissipation part.

Preferably, the average particle size of the low electrical resistance conductive powder may be in a range from 0.01 μm to 400 μm.

Preferably, the thickness of the circuit layer may be in a range from 0.005 mm to 0.2 mm.

The heat dissipator having a circuit formed by screen printing or spraying of the present invention has a screen printed or sprayed circuit layer formed on the heat dissipation part for coupling one to the other without the need of an additional circuit board. Additionally, the present invention has the advantages of low cost and a simplified manufacture process.

### BRIEF DESCRIPTION OF THE DRAWINGS

FIG. 1 is a first cross section view of a heat dissipator having a circuit formed by screen printing or spraying of the present invention.

FIG. 2 is a first schematic diagram showing a heat dissipator having a circuit formed by screen printing or spraying of the present invention.

FIG. 3 is a second schematic diagram showing a heat dissipator having a circuit formed by screen printing or spraying of the present invention.

FIG. 4 is a second cross section view of a heat dissipator having a circuit formed by screen printing or spraying of the present invention.

FIG. 5 is a schematic diagram showing a heat dissipation part of a heat dissipator having a circuit formed by screen printing or spraying of the present invention.

### DESCRIPTION OF THE PREFERRED EMBODIMENTS

The technical features, content, advantages and effects of the present invention will be presented hereinafter through embodiments accompanied with corresponding figures. The figures are only for the purpose of illustration and example, and do not necessarily imply the actual dimensions or precise configuration of the possible implementations of the present invention. Therefore, the present invention should not be limited by the dimensions or configuration shown in the figures.

The advantages, features, and approaches of the present invention will be described in detail with embodiments and their corresponding figures. The present invention can also be approached in different ways and should not be considered to be limited by these embodiments. For those skilled in the art, the scope of the present invention can be more clearly, thoroughly, and completely delivered through these embodiments; however, the present invention is limited solely by the scope of the appended claims.

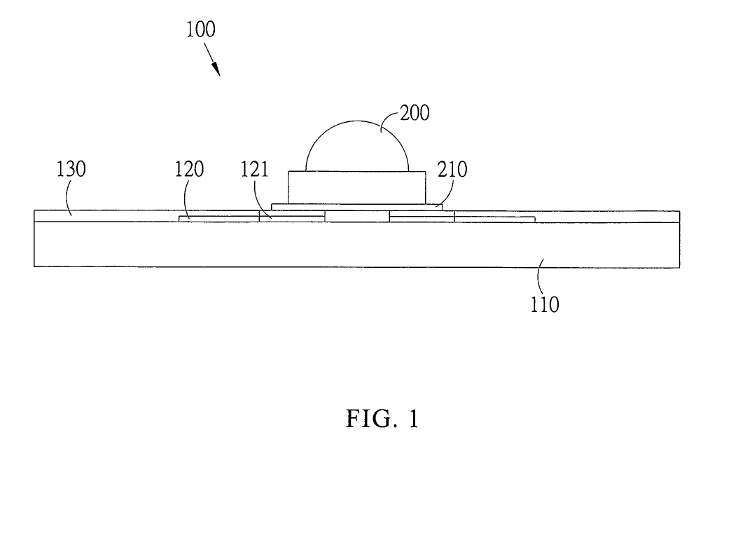

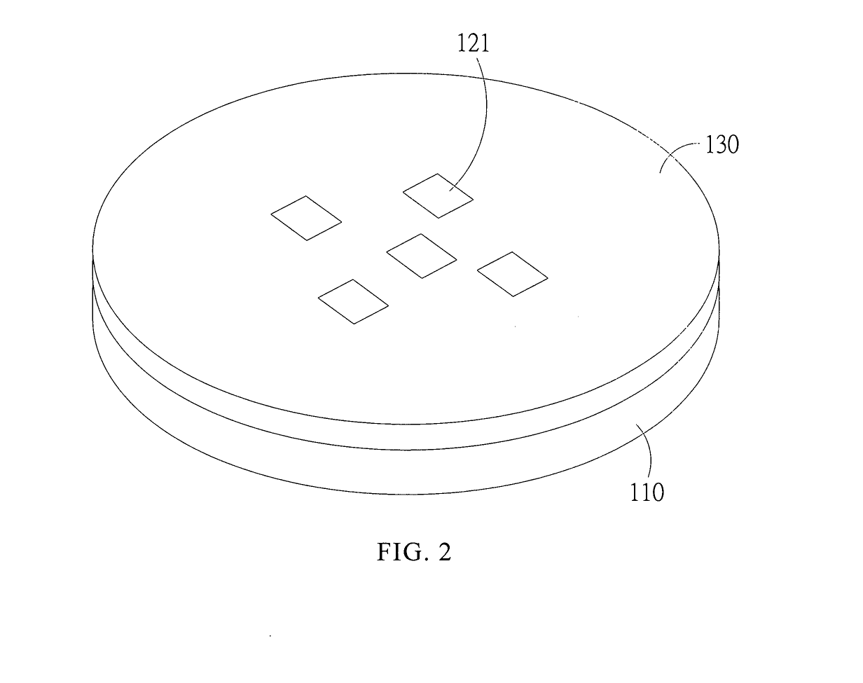

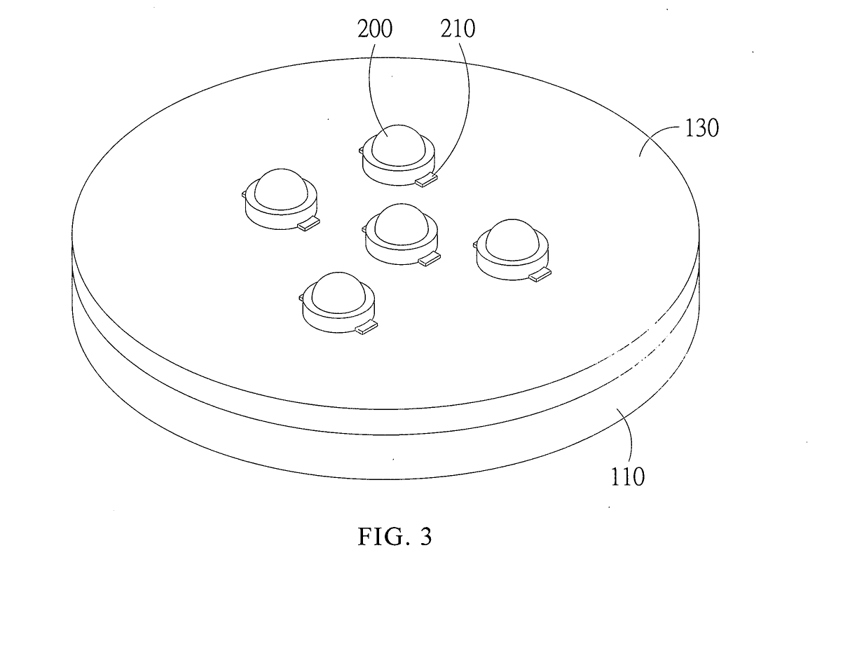

The following refers to FIGS. 1-3, where FIG. 1 is first cross section view of a heat dissipator having a circuit that is formed by screen printing or spraying of the present invention, FIG. 2 is a first schematic diagram showing a heat dissipator having a circuit that is formed by screen printing or spraying of the present invention, and FIG. 3 is a second schematic diagram showing a heat dissipator having a circuit that is formed by screen printing or spraying of the present invention. As shown in the figures, the heat dissipator 100 having circuit formed by screen printing or spraying includes a circuit layer 120 and an isolation layer 130.

The circuit layer 120 contains a uniformly distributed plastic material and low electrical resistance conductive powder and is formed by a method of screen printing or spraying. The circuit layer 120 is on one side of the heat dissipation part 110 of the heat dissipator 100, which has a circuit or circuits formed by screen printing or spraying.

On the circuit layer 120, there is at least one contact 121 for electrically connecting at least one pad or one pin of an electronic unit 200. The resistance of the circuit layer 120 may be as low as 10⁻¹Ω to 10⁻⁶Ω depending on the combination ratio of the plastic material and the low electrical resistance conductive powder. The circuit layer 120 is located on the surface of the heat dissipation part 110 and is surface treated or chemically nickel plated. The properties of the surface treatment may be in compliance with RoHS/WEEE regulations and may also improve the hardness, wear resistance, or reduce the resistance of the circuit layer 120 to meet the design requirements. The chemical nickel deposition may be selectively formed solely on the circuit layer 120 containing uniformly distributed plastic material and low electrical resistance conductive powder. The surface treatment method includes:

A step 1 of degreasing to remove residual grease on the surface of the heat dissipation part.

A step 2 of activating the circuit layer's surface by using an activator.

A step 3 of electroless nickel plating, wherein the bath may be composed of nickel sulfate serving as a nickel source, a complexation reagent, and other substances.

A step 4 of cleaning with hot water.

Typically, a combination of 5% to 70% of plastic material with 95% to 30% of low electrical resistance conductive powder are preferred for the circuit layer 120. The low electrical resistance conductive powder, the average particle size of which is preferably around 0.01 μm to 400 μm, may be a combination of irregular shaped particles selected from silver powder, silver copper powder, silver aluminum powder, silver nickel powder, copper powder, etc.

As for the plastic material, it may be one or a combination of two or more materials selected from epoxy resin, phenolic resin, acrylic resin, polyvinyl acetate (PVAc), silicone resin, synthetic rubber, etc.

During the manufacturing process, the low electrical resistance conductive powder and the plastic material are mixed and then placed on the heat dissipation part 110 to form the circuit layer 120 with a thickness of 0.005 mm to 0.2 mm by a method of screen printing or spraying. Because of the molecular structure of the plastic material, the particles of the low electrical resistance conductive powder are firmly fixed in their positions, and the circuit layer 120 may function as well as a copper foil layer of a conventional printed circuit board.

An isolation layer 130, which is disposed on the circuit layer 120 and the surface of the heat dissipation part 110, may act like a solder resist. The isolation layer 130 may greatly reduce the thermal resistivity and dissipate the heat generated from the ICs or devices directly and rapidly through the whole surface, and this may preserve the performance and increase the lifetime of the electronic unit 200, which is preferably, but not limited to, a light emitting diode.

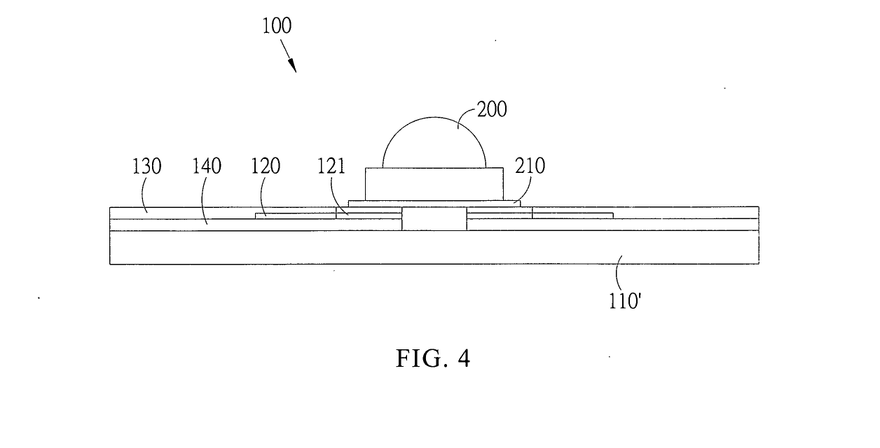

The aforementioned heat dissipation part 110 may effectively dissipate the heat generated by the electronic unit 200 and may be made of metal, ceramic, graphite, glass, plastic (conductive plastic), etc. The following refers to FIG. 4, which is a second cross section view of a heat dissipator having a circuit formed by screen printing or spraying of the present invention. As show in the figure, there may be a heat conductive isolation layer 140 disposed between the metal heat dissipation part 110′ and the circuit layer 120, when the heat dissipation part is a metal heat dissipation part 110′. The heat conductive isolation layer 140 may be formed by screen printing or spraying a material containing uniformly distributed heat conductive powder.

The heat conductive isolation layer 140 may include the heat conductive powder and a dispersion liquid used to contain the particles of the heat conductive powder. A mixing process may be performed to uniformly distribute the powder in the dispersion liquid. The heat conductive powder is a powder with high electrical resistance including one or more materials selected from the group of aluminum oxide, aluminum nitride, boron nitride, silicon carbide, etc., such that the heat conductive isolation layer 140 may have high resistivity from 10⁻⁶Ω·cm to 10⁻¹⁹Ω·cm. The heat conductive powder may include crystalline particles with spherical or irregular shape. The average particle size is preferably about 0.01 μm to 100 μm.

The heat conductive powder is treated. The treatment process includes hydrolysis carried out by dissolving, for example by soaking, a fluorine compound or organosilicon in ethanol or isopropyl alcohol, adding one or more of the aforementioned heat conductive powder materials, mixing a resulting solution, and finally baking the solution at a low temperature of around 60° C. to 150° C. to remove the air and water molecules, such that a heat conductive dry ceramic powder may be acquired. Following this treatment, the heat conductive powder is completely coated with a layer of the fluorine compound or organosilicon which promotes dispersion of the powder particles by preventing the sintering crystallization or intermolecular crosslinking between the powder particles.

The procedure of the method used to prepare a liquid material to combine with the heat conductive powder may be as follows: organosilicon modified phenol formaldehyde monomer, or organosilicon (organosilicon modified epoxy, phenolic, or polyester), and elastic rubber materials such as nitrile butadiene, neoprene, or Thiokol are sequentially added and dissolved in a solvent mixture including, for example, one or more alcohols, methyl ethyl ketone (MEK), ether, and other solvents in order to dissolve each of the added solutes. Then, a small amount of filler such as a (AlOH+H20+ethanol) sol is added to the solution and thoroughly mixed to finally acquire the liquid material to combine with the heat conductive powder. The heat conductive isolation layer 140 may be formed from a combination of the liquid material and the heat conductive powder in a certain ratio to acquire the desired material properties for the heat conductive isolation layer 140, including heat conductivity, flexibility, temperature tolerance, shearing strength, aging resistance, peel strength, abrasion resistance, impact strength, etc. Typically, a weight ratio of 3% to 15% of the liquid material and 97% to 85% of the heat conductive powder is used to form the isolation layer 140 with a heat transfer coefficient of around 3 W/mK to 150 W/mK.

After mixing the liquid material together with the heat conductive powder, the resulting mixture is applied between the heat dissipation part 110′ and the circuit layer 120 by repeatedly laying down layer upon layer for several layers through a method of coating, spraying, screen printing, etc. to form a thickness of 0.01 mm to 15 mm of the heat conductive isolation layer 140. Due to the molecular structure of the liquid material, the particles of the heat conductive powder are firmly fixed to their dispersed positions.

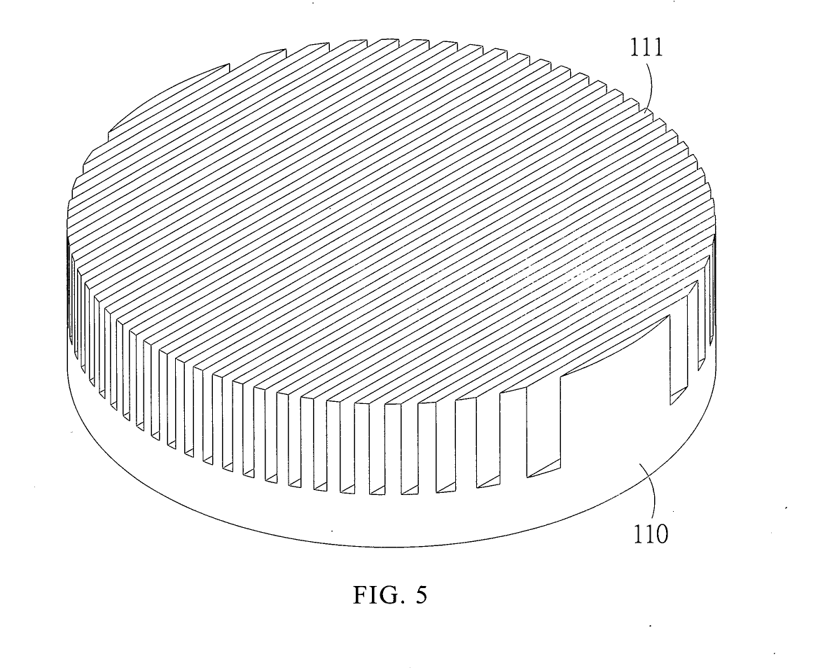

The following refers to FIG. 5, which is a schematic diagram showing a heat dissipation part of a heat dissipator having a circuit formed by screen printing or spraying of the present invention. As shown in the figure, the other side of the heat dissipation part 110 (opposite to the surface having the circuit layer) may have a plurality of fins 111 to increase the rate of heat dissipation.

In summary, the heat dissipator having a circuit formed by screen printing or spraying has a circuit layer formed by screen printing or spraying on the heat dissipator for coupling one to the other without the need of an additional circuit board, providing the advantages of low cost and a simplified manufacture process. In addition, the circuit layer 120 and the isolation layer 130 are disposed on one side of the heat dissipator having a circuit formed by screen printing or spraying, which binds the circuit and heat dissipation functions together to directly and rapidly dissipate the heat through the overall structure and greatly reduces the thermal resistivity, which may preserve the performance and increase the lifetime of the electronic unit.

The purpose of the described embodiments is to illustrate the technical ideas and features of the present invention, such that one skilled in the art can comprehend the contents of the present invention and practice said invention accordingly. It should be understood, however, that the invention is not to be limited to the particular form disclosed; rather, the invention is to cover all modifications, equivalents, and alternatives falling within the spirit and scope of the appended claims.

1. A heat dissipator having a circuit formed by screen printing or spraying, comprising:
a circuit layer, which is formed by screen printing or spraying a uniformly distributed plastic material and a low electrical resistance conductive powder and is disposed on a surface of a heat dissipation part of the heat dissipator having the circuit formed by screen printing or spraying, and
an isolation layer disposed on the surface of the heat dissipation part and the circuit layer.

2. The heat dissipator having a circuit formed by screen printing or spraying of claim 1, wherein the heat dissipation part is a metal heat dissipation part, and a heat conductive isolation layer is disposed between the metal heat dissipation part and the circuit layer by screen printing or spraying a material containing a uniformly distributed heat conductive powder.

3. The heat dissipator having a circuit formed by screen printing or spraying of claim 2, wherein the heat conductive powder includes crystalline particles with spherical or irregular shape.

4. The heat dissipator having a circuit formed by screen printing or spraying of claim 2, wherein the particle size of the heat conductive powder is from 0.01 μm to 100 μm.

5. The heat dissipator having a circuit formed by screen printing or spraying of claim 2, wherein the thickness of the heat conductive isolation layer is from 0.01 mm to 15 mm.

6. The heat dissipator having a circuit formed by screen printing or spraying of claim 1, wherein there are a plurality of fin structures on the other surface of the heat dissipation part.

7. The heat dissipator having a circuit formed by screen printing or spraying of claim 1, wherein the heat dissipation part is a ceramic heat dissipation part, a plastic heat dissipation part, or a glass heat dissipation part.

8. The heat dissipator having a circuit formed by screen printing or spraying of claim 1, wherein the average particle size of the low electrical resistance conductive powder is from 0.01 μm to 400 μm.

9. The heat dissipator having a circuit formed by screen printing or spraying of claim 1, wherein the thickness of the circuit layer is from 0.005 mm to 0.2 mm.
